(19) United States
(12) Patent Application Publication
(10) Pub. No.: US 2023/0092548 A1
(43) Pub. Date: Mar. 23, 2023

(54) SCALABLE EOS AND AGING TOLERANT LEVEL SHIFTER FOR A HIGH VOLTAGE DESIGN FOR THIN GATE TECHNOLOGY

(71) Applicant: Intel Corporation, Santa Clara, CA (US)

(72) Inventors: Raj Dua, Ludhiana Punjab (IN); Hari Vijay Venkatanarayanan, Bengaluru (IN)

(21) Appl. No.: 17/482,912

(22) Filed: Sep. 23, 2021

(51) Int. Cl. H03K 19/0185

(52) U.S. Cl. CPC H03K 19/018507

(57) ABSTRACT

A level shifter circuit, comprising one or more thin gate transistors having source and drain terminals coupled, respectively, to a power supply node and a reference node, where the one or more thin gate transistors have an electrical over stress (EOS) threshold voltage that is lower than a voltage of the power supply applied across two terminals of the one or more thin gate transistors. The circuit further includes a PFET pulldown circuit coupled to an EOS protection circuit to limit the voltage difference across at least two terminals of the one or more thin gate transistors to a voltage below the EOS threshold voltage based on the threshold voltage the PFET.

### TECHNICAL FIELD

The document pertains generally, but not by way of limitation, to integrated circuits, and more particularly, to techniques for a voltage level shifter.

### BACKGROUND

Microprocessors and other data processing devices typically include core logic circuitry, such as circuitry that is configured to execute software applications or to perform data processing operations, and input-output (I/O) interface circuitry, such as circuitry that is configured to interface with, or to exchange data or other signals between, devices that are external or remote to the microprocessor. To reduce power dissipation and to, among other things, enable the continuing reduction in integrated circuitry device sizes, microprocessor core logic circuitry is typically operated at or about the minimum voltage (hereinafter, “core voltage”) allowable by a semiconductor fabrication process node. Input-output circuitry, however, generally operate at voltages (hereinafter, “I/O voltage” or “I/O voltages”) higher than this core voltage, such as to improve signal integrity or to enable high speed communication over the relatively long distances between devices or components of a system. A voltage level shifter, such as the high-speed level shifters typically employed in high-speed memory I/O interface such as double data rate (DDR) memory and high bandwidth memory (HBM), are used in processors to convert, or shift the voltages of signals generated by core logic circuitry to voltages in the range of the I/O circuitry.

A concern in the implementation of level shifter circuitry is electrical over stress (EOS) and device aging, such as caused by applying a voltage a cross a device (e.g., across two terminals of a device) that exceeds an operating parameter of the devices, such as an EOS target or threshold voltage of a transistor. EOS can degrade the performance of a device and accelerate device aging. Several techniques for building level shifters attempt to address these concerns. One technique, for example, includes the use of thick gate devices, such as semiconductor devices that have a gate oxide that is suitably thick to cause the devices to have an EOS target of threshold that exceeds the range of I/O voltages used in I/O interface circuitry. Another technique includes the use of thin gate devices, such as devices that may be susceptible to EOS damage when operated at voltages in the range of I/O voltages used in I/O interface circuitry, along with an elevated ground signal, such as a reference signal that is offset to a higher voltage than a ground or reference used by the core logic, to protect devices that are exposed to I/O voltages. Such device protection includes using the elevated reference to limit maximum voltage across the device.

### BRIEF DESCRIPTION OF THE DRAWINGS

In the drawings, which are not necessarily drawn to scale, like numerals may describe similar components in different views. Like numerals having different letter suffixes may represent different instances of similar components. Some examples are illustrated by way of example, and not limitation, in the figures of the accompanying drawings.

FIG. 1 includes a diagram of an example of a level shifter that includes one or more pulldown p-channel field effect transistors.

FIG. 2 illustrate a diagram of an example of circuitry for using a p-channel field effect transistor in a pulldown configuration to provide EOS protection to one or more p-channel field effect transistors in level shifter.

FIG. 3 illustrates a diagram of an example of circuitry for using a two or more p-channel field effect transistors in a pulldown configuration to provide EOS protection to one or more p-channel field effect transistors in level shifter.

FIG. 4 illustrates a diagram of an example of a level shifter that uses pulldown p-channel field effect transistors to provide EOS protection.

FIG. 5 illustrates a diagram of an example of a level shifter that uses pulldown p-channel field effect transistors to provide EOS protection.

FIG. 6 illustrates a diagram of an example of output circuitry for a I/O interface that includes a level shifter and formed by thin p-channel field effect transistors.

FIG. 7 illustrates steps for a process 700 for forming a level shifter that provides EOS protection to thin gate devices.

### DETAILED DESCRIPTION

Aspects of the present disclosure are based on the inventors' realization that existing techniques for shifting the voltage level of signals in an integrated circuit from a low voltage range, such as a core voltage range, to a higher voltage range, such as an I/O voltage range, is not suitable for some applications and can inhibit or limit progress in current trends towards forming smaller, faster, and lower power integrated circuit devices and systems. In example, fabrication costs associated with level shifting techniques that use thick gate devices can be high as such techniques can require a semiconductor manufacturer to support or implement both thick gate and thin gate fabrication technologies. These costs can be prohibitive as many semiconductor manufacturers, such as companies having a microprocessor or device chipset business, prefer to use a single technology, such as thin gate device technology, to optimize manufacturing costs and to maximize device performance. In another example, level shifting techniques that use thin gate devices with an elevated reference can incur increased manufacturing costs, such as in terms of die area, power consumption, engineering design and support efforts. Additionally, such techniques may be challenging to scale higher data rates. In another example, generating and using an elevated reference can consume a large amount of die area due to the addition of analog circuitry, such as voltage regulators, added power supply tracks or wires, and the addition of capacitor banks and other devices for noise suppression. Such techniques can also experience increased power consumption, such as due to current leakage caused by the elevated reference leaving some devices partially turned on while a device is energized. This can require increases to a device's power budget which can limit the ability to scale such devices to higher data rates. Engineering costs can also be increased due to the need to design, validate, and tune the additional analog circuitry.

Aspects of the present disclosure include techniques (e.g., circuits, devices, systems, or methods) for an EOS and aging robust level shifter that addresses the disadvantages of existing level shifter techniques. In an example, the techniques disclosed herein include a level shifter formed using thin gate devices (e.g., transistors) that are protected from EOS by one or more thin gate p-channel field effect transistors (PFETs) that are configured as pulldown devices. Such PFETs are configured to limit or reduce the voltage across the protected devices by at least one PFET threshold voltage (Vₜₚ) drop below the high voltage supply of the level shifter. In an example, the PFETs in the pulldown configuration (hereinafter, “pulldown PFET” or “pulldown PFETs”) generate gate signals for the protected PFET devices that have a voltage swing between the high supply voltage of the level shifter and at least one Vₜₚ drop above the voltage reference or ground rail of the level shifter. This technique can be used, such as by adding one or more additional Vₜₚ drops using one or more additional pulldown PFETs, to provide any suitable voltage drop to limit the EOS voltage across a protected device to an EOS target or threshold voltage.

In an example, a level shifter is fabricated using thin gate field effect transistors (FETs). The thin gate FETs include one or more pulldown PFETs that provide a constant voltage drop of at least one Vₜₚ to limit the voltage across PFETs that are exposed to the high voltage supply of the level shifter to a voltage below the EOS target or threshold for the devices. The voltage across the protected PFETs is limited or obtained by using the pulldown PFETs to generate gate signals for the protected devices that are at least one Vₜₚ drop above the reference voltage of the level shifter.

By using the pulldown PFETs to limit EOS voltage across thin FET devices, the level shifters formed according to the techniques described herein provide EOS and aging robustness without the use of thick gate devices or elevated ground supply references. This enables fabrication of EOS and aging robust level shifters using just a thin gate process, and eliminates the analog circuitry, increased die area, and associated analog design considerations that would otherwise be need for level shifters that use an elevated ground supply.

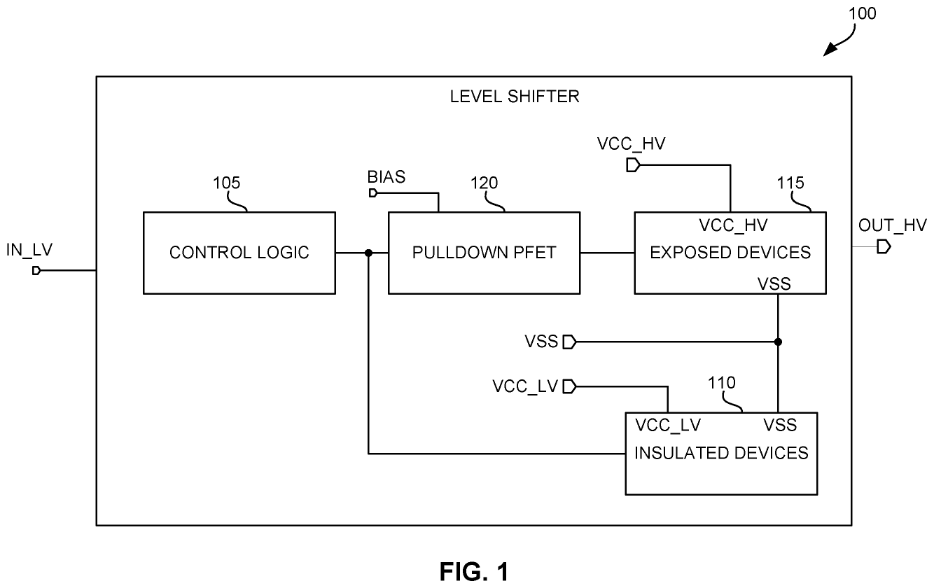

FIG. 1 includes a diagram of an example of a level shifter 100 that includes one or more pulldown PFETs. Level shifter 100 can include circuitry or a data structure, such as a circuit layout file of a computer aided design software application used in integrated circuit fabrication, for implementing any of the level shifters described herein. In an example, lever shifter 100 is used in microprocessor circuitry to convert the voltages of signals IN_LV generated by core logic circuitry of the microprocess to the voltage levels of I/O circuitry associated with the processor. The core logic can be configured to generate low voltage signals IN_LV that have voltage swings (e.g., a maximum voltage swing) between the low voltage supply rail VCC_LV and reference or ground rail VSS (hereinafter, “low voltage domain”). In an example, VSS_LV or the maximum voltage of IN_LV is less than a minimum indicated voltage for safely or reliably actuating or driving devices that are configured to operate with voltage swings between the high voltage supply VCC_HV and VSS (hereinafter, “high voltage domain”). Level shifter 100 is configured to receive VCC_LV, VCC_HV, VSS, and low voltage signal IN_LV. Level shifter 100 is further configured to shift the low voltage signal IN_LV to the high voltage signal OUT_HV, where OUT_HV has a voltage swing between VCC_HV and VSS. OUT_HV in various examples, has a maximum high voltage of VCC_HV and a maximum low voltage of VSS.

In an example, level shifter 100 includes control logic 105, insulated devices 110, exposed devices 115, and pulldown PFET 120. Each component of the level shifter 100, in various examples, is implemented using thin gate FETs. In other examples, level shifter 100 and one or more of its associated components are implemented using one or more other semiconductor device technology or process.

Control logic 105 includes circuitry that is configured to receive low voltage signal IN_LV (e.g., a signal in the core logic voltage domain) and to actuate, such as by providing biasing voltages or other control signals, one or more components of level shifter 100 to shift or convert IN_LV to high voltage output signal OUT_HV (e.g., a signal in the I/O voltage domain). In an example, the circuitry of control logic 105 is not exposed to VCC_HV. In other examples, control logic 105 includes devices is exposed to both VCC_HV and VCC_LV. In such examples, the exposed devices are protected by pulldown PFET 120, as described herein.

Insulated devices 110 include circuitry that is configured to be actuated or driven by control logic 105 to shift or convert IN_LV to high voltage output signal OUT_HV. In an example, insolated devices 110 includes devices that are coupled to VCC_LV and VSS and are insulated from, or are not exposed to, VCC_HV. Insulated devices 110 include, for example, control logic devices that are supplied by VCC_LV and VSS, and n-channel field effect transistors (NFETs) that form, or that are used to protect, the pulldown circuitry in the output stage of level shifter 100.

Exposed devices 115 include circuitry that is configured to be actuated or driven by control logic 105 to shift or convert IN_LV to high voltage output signal OUT_HV. Such circuitry, in various examples, include PFETs that are coupled to VCC_HV and VSS. Such PFETs can include PFETs that form the pullup circuitry in the output stage of the level shifter 100. Such PFETs can additionally include control logic PFETs that are configured to actuate the pullup circuitry or to steer signals to such circuitry.

Pulldown PFET 120 includes one or more PFETs that are configured as pulldown devices to provide EOS protection to exposed devices 115. Such protection includes, in various examples, pulldown PFET 120 generating gate signals that switch between VCC_HV and one or more Vₜₚ drops above VSS. In an example pulldown PFET 120 can include two or more PFET devices that are cascaded to provide a suitable number of Vₜₚ drops. ca Such protection includes, in other examples, pulldown PFET 120 providing a one or more Vtp drop between the drain of a PFET and a references node, such as VSS. This technique provides EOS protection by limiting the maximum gate-to-drain voltage V_{GD} or gate-to-source voltage V_{GS} a protected PFET to a value determined by VCC_HV and the number of Vₜₚ drops provided by PFET 120. The number of Vₜₚ drops (e.g., the number of cascaded PFETs) used to obtain a specified level of EOS protection can be determined based on, for example, the difference between VCC_HV (e.g., the maximum voltage that may be dropped across an exposed PFET in the level shifter 100) and an indicated EOS target or threshold voltage for the protected device. In an example, if VCC_HV is 1.133V and the PFETs in level shifter 100 has an EOS target of 0.9V, then two cascaded PFETs can be used to provide two Vtp voltage drop to satisfy the EOS target requirement. In some examples, pulldown PFET 120 includes one or more biasing or offsetting signals BIAS to adjust the level of EOS protection by selectively decreasing or increasing the gate biasing or drain voltage drop provided by pulldown FET 120.

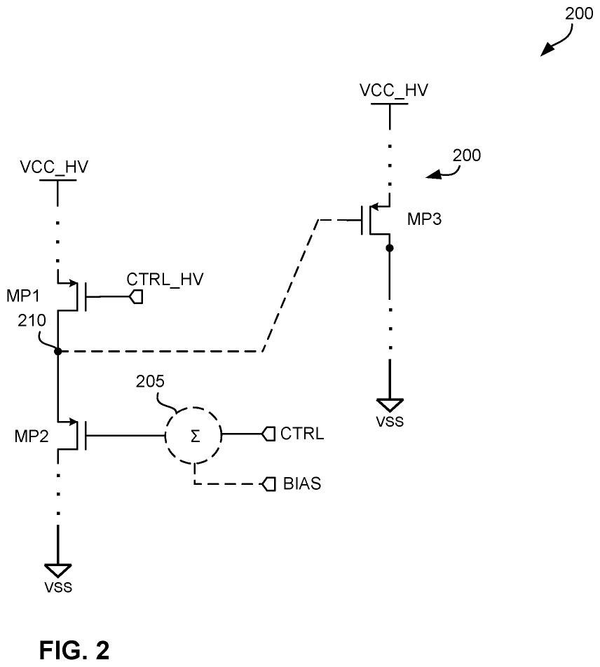

FIG. 2 illustrate a block diagram of an example of circuitry 200 for using a PFET MP2 in a pulldown configuration to provide EOS protection to one or more PFETs MP1 and MP3 in level shifter. Circuitry 200 is an example of circuitry that can be used in level shifter 100, such as to protect exposed devices 115. Circuitry 200 includes PFETs MP1, MP2, and MP3. In some examples, circuitry 200 includes bias circuitry 205. Bias circuitry 205 can include any circuitry that is configured to add a voltage bias to control signal CRTL used to drive the gate of MP2.

Transistors MP1 and MP3 are examples of exposed PFET devices, such as exposed devices 115, that are exposed to a voltage supply having a reference voltage rail VSS and a high voltage rail VCC_HV that exceeds an EOS target or threshold voltage of the devices. Such devices may be susceptible to EOS due to their connection across VCC_HV and VSS.

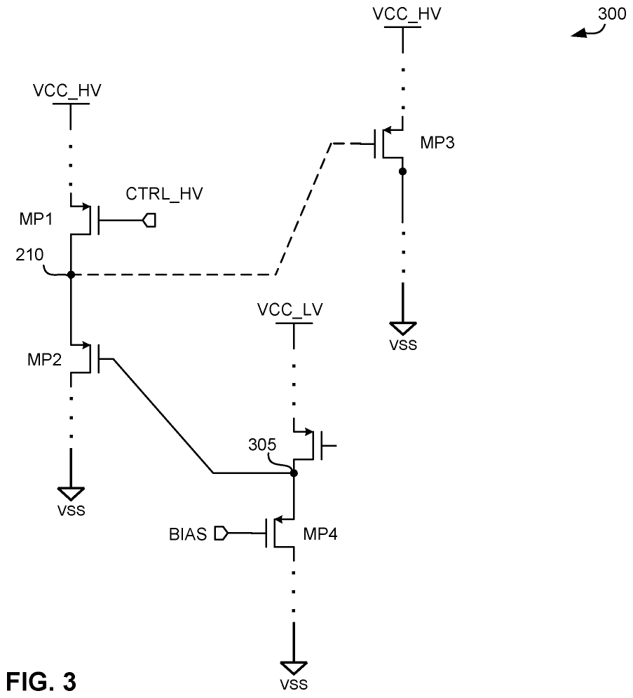

Transistor MP2 is an example of a PFET, such as pulldown PFETs 120, that is configured or arranged in a pulldown configuration to provide EOS protection to MP1 and MP3. As shown in FIG. 2, MP2 is configured as a pulldown transistor (e.g., MP2 has a pulldown configuration) as it is deployed in a stacked configuration and its source is not coupled to the high voltage rail VCC_HV. MP2 has a gate that is driven by control signal CTRL and, optionally, bias or offset signal BIAS. In an example, CTRL is combined with BIAS such that the gate voltage V_{G} of MP2 is the sum, or another suitable aggregation function determined by biasing circuitry 205, of the voltages of CTRL and BIAS. Unless indicated otherwise, CTRL is assumed to include BIAS for the remainder of this discussion. CTRL drives the gate of MP2 such that MP2 turns on or conducts when the source voltage Vs of MP2 exceeds V_{G} (e.g., voltage of CTRL) by Vₜₚ (e.g., the threshold voltage of MP2) and MP2 is turned off when Vs drops below the sum of V_{G} and Vₜₚ. In this pulldown configuration, MP2 is configured to pull the voltage at node 210 towards VSS responsive to the V_{G} going, or being driven, low (e.g., V_{G} having a value of VSS or 0V). Transistor MP2 will not be able to pull node 210 to VSS at the transistor will turn off once the voltage at node 210 (e.g., Vs) is pulled below the voltage CTRL+Vₜₚ. Accordingly, the minimum value of the voltage at node 210 is CTRL+Vₜₚ. This value is smallest when MP2 fully turned on. Since MP2 is typically driven to turn on fully by driving CTRL low, or to 0V, the minimum voltage at node 210 is Vₜₚ, or the sum of Vₜₚ and BIAS. This minimum voltage can be increased by any integer multiple of Vₜₚ by cascading two or more pulldown PFETs, such as shown in FIG. 3.

In operation, transistors MP1, MP3 can experience EOS when a voltage across any two terminals of the devices exceeds an EOS target or threshold for the device. In a configuration of circuitry 200 where VCC_HV exceeds, or is higher than the EOS target of MP1 or MP3, transistor MP2 can protect each of these devices by ensuring a minimum voltage at node 210.

In an example, MP2 protects MP3 from gate-to-source voltage (V_{GS}) EOS by providing or ensuring a specified minimum voltage at the gate of MP3 (e.g., the voltage at node 210). If, for example, VCC_HV is within one Vₜₚ of the gate-to-source EOS target of MP3, then a one Vₜₚ minimum voltage provided by MP2 at node 210 ensures that the V_{GS} of MP3 doesn't exceed the EOS target, thereby limiting the likelihood of V_{GS} EOS. Without MP2, V_{GS} of MP3 could exceed the EOS target, such as when the V_{G} of MP3 is driven to 0V to turn on the transistor. In another example, if VCC_HV is within two Vtp of the gate-to-source EOS target of MP3, then two transistors MP2 can be cascaded, such as shown in FIG. 3, to provide a two Vₜₚ minimum voltage at node 210, ensuring that the V_{GS} of MP3 does not exceed the EOS target, thereby limiting the likelihood of V_{GS} EOS. A pulldown PFET mirroring MP2 can be used to provide similar V_{GS} EOS protection to M1.

In another example, MP2 protects MP3 from gate-to-drain (V_{GD}) EOS by providing or ensuring a specified the minimum voltage at the drain of MP3 (e.g., node 210). In an example where MP2 is not included in circuitry 200, V_{GD}can exceed the gate-to-drain EOS target of MP1, such as when V_{G} of MP1 is driven high to VCC_HV. Transistor MP2, or one or more cascaded versions of MP2, can protect MP1 from V_{GD}by ensuring a specified minimum voltage at the drain of MP1 that is an indicated multiple of Vₜₚ. A pulldown PFET mirroring MP2 disposed between the drain of MP3 and VS S can be used to provide similar VGD EOS protection to MP3.

FIG. 3 illustrates a diagram of an example of circuitry 300 for using a two or more PFETS in a pulldown configuration to provide EOS protection to one or more PFETs MP1 and MP3 in level shifter. Circuitry 300 is an example of circuitry 200, modified to include a second pulldown PFET MP4 to provide an additional Vₜₚ drop at node 210, such as to increase the minimum voltage at node 210 to 2×Vₜₚ. As shown in FIG. 3, MP4 is coupled to the voltage supply VCC_LV. In some, examples, however, MP4 can be coupled to VCC_HV.

In operation, the pulldown operation of MP4 provides a minimum voltage at node 305 of Vₜₚ. This minimum voltage is coupled to the gate of MP2, thereby providing a minimum voltage at node 210 is 2×Vtp.

MP4 is additionally configured as an example of bias circuit 205, such as by providing a means to offset the voltage at the gate of MP2, or at nodes 210 or 305, by bias signal BIAS. In an example BIAS, as shown in FIGS. 2 and 3, is generated locally, such as within the level shifter or on a microprocessor die, and has a selectable or adjustable value that can be used to provide additional EOS protection margin, such as by setting or determining a higher minimum valve for the nodes 210 or 305. In an example BIAS has a value between 0V and 250 mV.

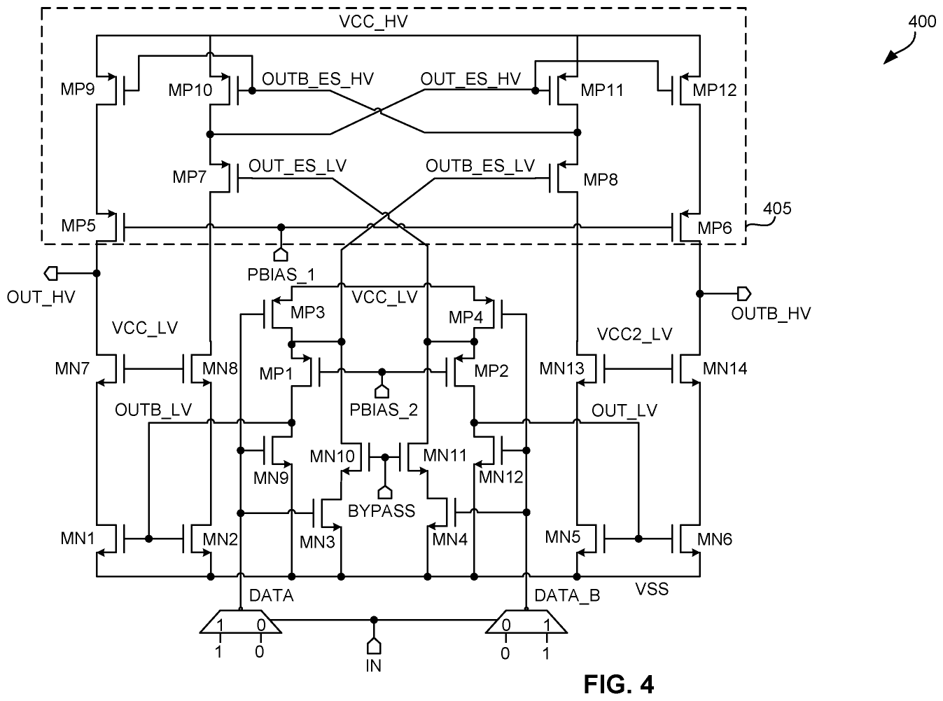

FIG. 4 illustrates a diagram of an example of a level shifter 400 that uses pulldown PFETs to provide EOS protection. Level shifter 400 is an example of level shifter 100 (FIG. 1), and is configured to shift, for example, digital input signals IN that switch between low voltage domain voltage rails VCC_LV and VSS to output signals OUT_HV or OUTB_HV that switch between a high voltage domain rails VCC_HV and VSS. In an example, level shifter 400 is formed using thin FETs, such that the EOS target or threshold of the FETs are less than the voltage difference between VCC_HV and VSS. Level shifter 400 is further configured to use a single reference VSS (e.g., a 0V or true ground reference) to perform the indicated level shifting operations.

As shown in FIG. 4, circuitry 405 includes one or more devices that are exposed to VCC_HV, and therefore require EOS protection. In an example, PFET devices MP5-MP12 are exposed to VCC_HV, while NFETs MN1-MN14 are insulated from this voltage rail. PFETs MP1-MP4 are similarly insulated or isolated from VCC_HV and therefore do you require additional EOS protection. Transistors MP1, MP2, MPS, MP6, MP7, and MP8 are configured as pulldown PFETs, such as MP2 (FIG. 2) and MP4 (FIG. 3), to provide EOS protection to MP9, MP10, MP11, and MP12.

In operation, level shifter 400 is configured to operate in a normal mode, such as for level shifters formed using FETs that have a low Vₜₚ (e.g., thin FETS having a threshold voltage between 0.1-0.3V) and a bypass mode, such as for level shifters formed using FETs having a large Vₜₚ (e.g., a threshold voltage that exceeds the low Vₜₚ range). In an example, the level shifter mode of operation is selected through actuation of signal BYPASS.

Gate-to-source voltage EOS can be caused by a voltage between the gate and source of a PFET that exceeds an EOS target or threshold, such as when the transistors turned-on (e.g., V_{G} is at or approaches a low voltage, such as VSS). In normal mode, V_{GS} EOS protection for MP9, MP10, MP11, and MP12 is provided by gate signals that switch between VCC_HV and 2×Vₜₚ above bias voltage pbias_ 2, where pbias_ 2 is a gate offset voltage such as BIAS (FIGS. 2 and 3). Bias voltage pbias_ 2 controls the level of V_{GS} EOS protection provided in normal mode. As pbias_ 2 is increased, the voltage at the source of, for example, MP1 or MP2, is increased thereby increasing the voltage at the gate of MP7 or MP8. This in turn increases the voltage at the gates of MP9, MP10, MP11, and MP12, thereby reducing V_{GS} of these transistors, such as when the transistors are actuated to turn on. Reduced V_{GS} corresponds to improved VGS EOS protection. In an example, pbias_2 can be adjusted between 0V-250 mV.

A gate voltage OUT_ES_HV and OUTB_ES_HV that is 2×Vₜₚ above pbias_ 2 is obtained at the gates of MP9, MP10, MP11, and MP12 are obtained as follows. Transistors MP1 and MP2 generates complementary signals OUT_ES_LV and OUTB_ES_LV at the source of these transistors. Signals OUT_ES_LV and OUTB_ES_LV switch between VCC_LV and pbias_2+Vtp, such as due to the pulldown configuration of the MP1 and MP2. Pulldown FETs MP7 and MP8 provide an additional Vₜₚ to the voltage drop between their gate and source nodes to provide a minimum voltage of pbias_2+2×Vₜₚ at their source, thereby ensuring that the gate voltages of MP9, MP10, MP11, and MP12 swing between VCC_HV and pbias_2+2×Vₜₚ.

Gate-to-drain voltage V_{GD}EOS can be caused by a voltage between the gate and drain of a PFET that exceeds an EOS target or threshold, such as when the transistors turned-off (e.g., V_{G} is at a high voltage, such as VCC_HV). The normal mode V_{GD}EOS protection provided to MP10 and MP11 is controlled by OUT_ES_HV and OUTB_ES_HV. As previously described, OUT_ES_HV and OUTB_ES_HV have a minimum voltage of pbias_2+2×Vₜₚ., which ensures that the maximum V_{GD}of MP10 or MP11 is VCC_HV- (pbias_2+2×Vₜₚ).

The normal mode V_{GD}EOS protection provided to MP9 and MP12 is controlled by pulldown FETs MP5, MP6, and bias or offset pbias_1. Due to the pulldown configuration of MP5 and MP6, the minimum value of the drain voltage of MP9 and MP12 is pbias_1+Vₜₚ. Signal pbias_ 1 can be adjusted to control the level or margin of V_{GD}EOS protection. In an example, pbias_ 1 has a value between 0V and 0.3×VCC_HV.

Transistors MP7 and MP8 may not require V_{GS} EOS protection due to the source and gate voltages of these transistors tracking each other.

In bypass mode, EOS protection for MP9, MP10, MP11, and MP12 is provided by gate signals OUT_ES_HV and OUTB_ES_HV that switch between VCC_HV and Vₜₚ. In this operating mode, NFETs MN3, MN4, MN10 and MN11 are used to pull OUT_ES_LV and OUTB_ES_LV to VSS, bypassing MP1 and MP2 and avoiding the Vₜₚ drop obtained from MP1 and MP2. Signals OUT_ES_HV and OUTB_ES_HV are generated with a single Vₜₚ drop at the source of MP7 and MP8, thereby ensuring a minimum V_{G} of Vₜₚ at the gates of MP9, MP10, MP11, and MP12.

Bypass mode V_{GD}EOS protection for the remaining PFETs are the same as discussed for VGD EOS protection for these devices in normal mode.

As discussed herein, level shifter 400 implements the pulldown PFET provided EOS protection techniques described in the discussion of FIGS. 1-3 to provide a level shifter that is formed using thin gate oxide devices and that provides EOS protection to devices exposed to an elevated supply VCC_HV without the use of an elevated reference or ground.

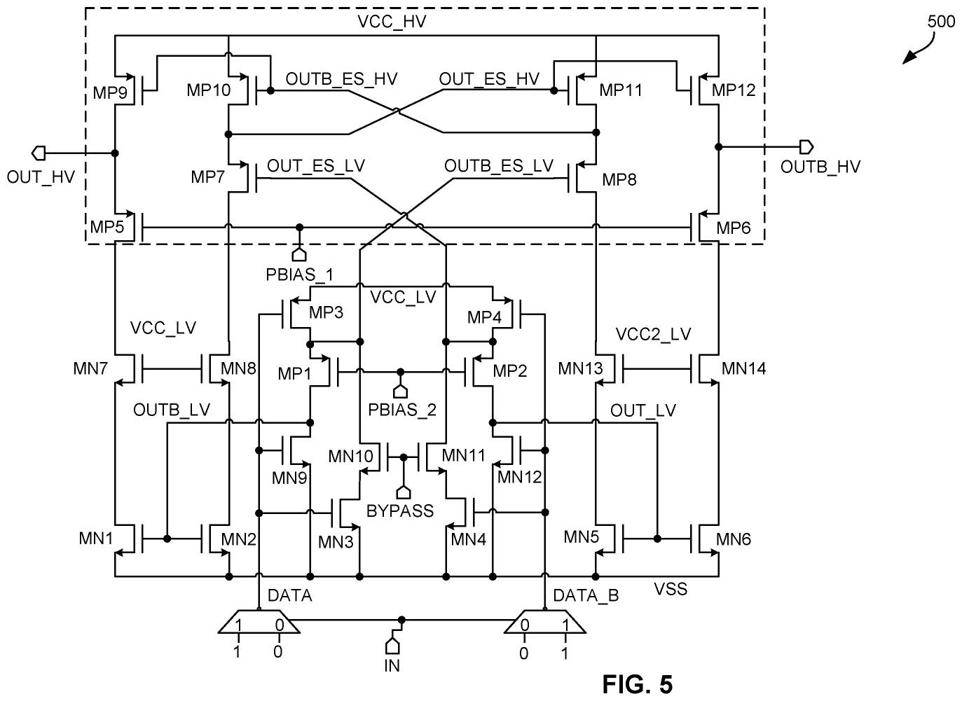

FIG. 5 illustrates a diagram of an example of a level shifter 500 that uses pulldown PFETs to provide EOS protection. Level shifter 500 is a modified version of level shifter 400, with the modification including obtaining the output of the level shifter from the source of MP5 and MP6 to limit the voltage swing of output signals OUT_HV and OUTB_HV, such as to values between VCC_HV and pbias_2+Vₜₚ. This modification can reduce the EOS impact at the output stage of level shifter 500, and thereby protect circuits connected to the output of the level shifter from EOS.

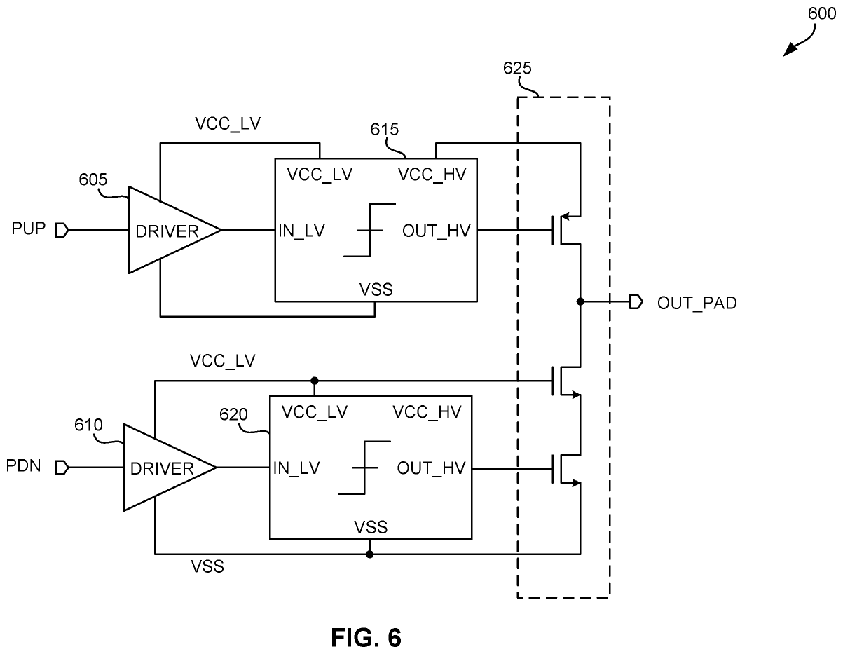

FIG. 6 illustrates a diagram of an example of output circuitry 600 for a I/O interface that includes level shifter 615 and 620 formed by thin FET devices, as described herein. In an example, output circuitry 600 includes pre-driver circuitry formed by drivers 605 and 610, level shifters 615 and 620, and output driver 625. Level shifters 615 and 620 are examples of any of the level shifters formed according to the techniques described herein. In a specific example, lever shifters 615 and 620 are included in the final stage of the pre-driver circuitry to limit the devices that are exposed to VCC_HV (e.g., an I/O supply voltage) to the devices in the level shifters and the output driver 625, while ensuring that final output signals of output circuitry 600 have a full rail-to-rail voltage swing, such as provided by final driver 625.

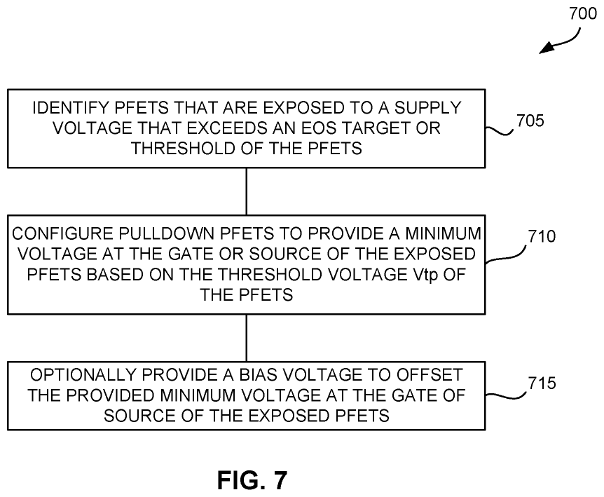

FIG. 7 illustrates steps of a process 700 for forming a level shifter that provides EOS protection to thin gate devices. Process 700 can be used, such as in a (CAD) software application, to form any of the level shifter circuitry formed according to the techniques described herein. A 705 one or more PFET devices that are exposed a supply voltage, such as VCC_HV, that exceeds an EOS target or threshold of the PFETs are identified. At 710, one or more PFETs are configured as pulldown devices to provide a minimum voltage at the gate or source of the exposed PFETs based on Vₜₚ of the pulldown devices. At 715, an optional bias or offset voltage is used to determine the a minimum voltage at the gate or source of the exposed PFETs, as described herein. Process 700 can further include any additional steps suitable for forming a level shifter according to the techniques described herein.

The circuits, circuitry, or devices illustrated in the figures and described herein are illustrated or described with respect to a specified electrical polarity, such as positive or negative voltages or currents, and device dopant or charge carrier configurations, such as PFET verses NFET or n-type material verses p-type material, to improve the clarity of the discussion. Such electrical polarities or devices dopant or charge carrier configurations can be reversed or swapped where readily appreciable without loss of generally to the techniques of devices described herein. Additionally, the present disclosure is applicable to both NFET and PFET devices.

Example 1 is a level shifter circuit, comprising: one or more p-channel field effect transistors (PFETs) having source and drain terminals coupled, respectively, to a power supply node and a reference node, wherein the one or more PFETs have an electrical over stress (EOS) threshold voltage that is lower than a voltage difference between the power supply node and the reference node; and a PFET pulldown circuit coupled to a first transistor of the one or more PFETs to limit the voltage difference across at least two terminals of a second PFET of the one or more PFETs to a voltage below the EOS threshold voltage based on the threshold voltage the PFET.

In Example 2, the subject matter of Example 1 includes, wherein the PFET pulldown circuit includes a PFET that is configured to as pulldown transistor to provide an indicated minimum gate voltage to the second PFET.

In Example 3, the subject matter of Example 2 includes, wherein the indicated minimum gate voltage is an indicated integer multiple of the threshold voltage of the PFET.

In Example 4, the subject matter of Example 3 includes, wherein the indicated minimum gate voltage includes a selectable offset voltage.

In Example 5, the subject matter of Examples 2-4 includes, the PFET has an electrical over stress (EOS) threshold voltage that is lower than a voltage difference between the power supply node and the reference node.

In Example 6, the subject matter of Examples 1-5 includes, wherein the PFET pulldown circuit includes a PFET that is configured to as pulldown transistor having a source terminal coupled a drain terminal of the second PFET to provide an indicated minimum gate voltage at the drain terminal of the second PFET.

In Example 7, the subject matter of Examples 1-6 includes, wherein the reference node is a coupled to a zero-volt power supply reference.

In Example 8, the subject matter of Examples 1-7 includes, wherein the at least two terminals of a second PFET includes a gate and source of the second PFET or a gate and drain of the second PFET.

Example 9 is a level shifter device to shift a voltage of a signal from a voltage level of first logic interface to a voltage level of a second logic interface, the device comprising: first and second power supply nodes to couple, respectively, to first and second power supplies, wherein the first power supply has a voltage that is lower than a voltage of the second power supply; a reference node to couple to a power supply reference that is shared by the first power supply and the second power supply; one or more transistors having a source terminal coupled to the second power supply node and a drain terminal coupled to the reference node to provide a shifted output signal responsive to an input signal, wherein the one or more transistors are degraded responsive to a voltage between at least two terminals of the one or more transistors exceeding a threshold value, the threshold value being smaller than a voltage difference between the second power supply and the power supply reference; and a pulldown transistor coupled to a first transistor of the one or more transistors to limit the voltage difference between the at least two terminals to a voltage below the threshold value based on the threshold voltage the pulldown transistor.

In Example 10, the subject matter of Example 9 includes, wherein at least one transistor of the one or more transistors is a p-channel field effect transistor (PFET).

In Example 11, the subject matter of Examples 9-10 includes, wherein the pulldown transistor includes a PFET having a first drain terminal coupled to the second power supply node and a first source terminal coupled to the reference node.

In Example 12, the subject matter of Example 11 includes, wherein the pulldown transistor is coupled between a first drain terminal of the first transistor and the reference node to limit a voltage at the first drain terminal of the first transistor to at least the threshold voltage the pulldown transistor.

In Example 13, the subject matter of Examples 11-12 includes, wherein: the pulldown transistor is coupled to a gate terminal of the first transistor; and to limit the voltage difference between the at least two terminals, the pulldown transistor is configured to limit a voltage at a first terminal of the at least two terminals to at least the threshold voltage the pulldown transistor.

In Example 14, the subject matter of Examples 9-13 includes, wherein the pulldown transistor is coupled between a pullup and pulldown transistor of a buffer circuit.

In Example 15, the subject matter of Examples 10-14 includes, wherein the pulldown transistor includes first and second PFETs, the first PFET having a first drain coupled to the first power supply node and a first source coupled to the reference node, the second PFET having a second drain coupled to the second power supply node and a second source coupled to the reference node.

In Example 16, the subject matter of Example 15 includes, a switching element that is configured to selectively bypass the first PFET.

Example 17 is a level shifter circuit, comprising: first and second power supply nodes to couple, respectively, to first and second power supplies, wherein the first power supply has a voltage that is lower than a voltage of the second power supply; a reference node to couple to a power supply reference that is shared by the first power supply and the second power supply; one or more p-channel field effect transistors (PFETs) having a source terminal coupled to the second power supply node and a drain terminal coupled to the reference node to provide a shifted output signal responsive to an input signal, wherein the one or more PFETs have an electrical over stress (EOS) threshold voltage that is lower than a voltage difference between the second power supply and the power supply reference; and a pulldown PFET coupled to a first transistor of the one or more PFETs to limit the voltage difference between the two terminals of the one or more PFETs to a voltage level below the EOS threshold voltage based on the threshold voltage the pulldown PFET.

In Example 18, the subject matter of Example 17 includes, wherein the reference node is coupled to a zero-volt power supply reference and pulldown PFET has an EOS threshold voltage that is lower than a voltage difference between the second power supply and the power supply reference.

In Example 19, the subject matter of Examples 17-18 includes, wherein the two terminals of the one or more PFETs includes a gate and source of the one or more PFETs or a gate and drain of the one or more PFETs.

In Example 20, the subject matter of Examples 17-19 includes, wherein: the pulldown PFET has a source terminal coupled to a drain or gate terminal of the one or more PFETs; and to limit the voltage difference between the two terminals of the one or more PFETs, the pulldown PFET is configured to limit a voltage at the drain or gate terminal the two terminals of the one or more PFETs to at least the threshold voltage the pulldown transistor.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

In the present disclosure, for purposes of explanation, numerous specific details are set forth in order to provide a thorough understanding of some example examples. It will be evident, however, to one skilled in the art that the present disclosure may be practiced without these specific details.

Examples, as described herein, may include, or may operate on, logic or a number of components, modules, or mechanisms. Modules may be hardware, software, or firmware communicatively coupled to one or more processors in order to carry out the operations described herein. Modules may be hardware modules, and as such modules may be considered tangible entities capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

Circuitry or circuits, as used in this document, may comprise, for example, singly or in any combination, hardwired circuitry, programmable circuitry such as computer processors comprising one or more individual instruction processing cores, state machine circuitry, and/or firmware that stores instructions executed by programmable circuitry. The circuits, circuitry, or modules may, collectively or individually, be embodied as circuitry that forms part of a larger system, for example, an integrated circuit (IC), system on-chip (SoC), desktop computers, laptop computers, tablet computers, servers, smart phones, etc.

As used in any example herein, the term “logic” may refer to firmware and/or circuitry configured to perform any of the aforementioned operations. Firmware may be embodied as code, instructions or instruction sets and/or data that are hard-coded (e.g., nonvolatile) in memory devices and/or circuitry.

“Circuitry,” as used in any example herein, may comprise, for example, singly or in any combination, hardwired circuitry, programmable circuitry, state machine circuitry, logic and/or firmware that stores instructions executed by programmable circuitry. The circuitry may be embodied as an integrated circuit, such as an integrated circuit chip. In some examples, the circuitry may be formed, at least in part, by the processor circuitry executing code and/or instructions sets (e.g., software, firmware, etc.) corresponding to the functionality described herein, thus transforming a general-purpose processor into a specific-purpose processing environment to perform one or more of the operations described herein. In some examples, the processor circuitry may be embodied as a stand-alone integrated circuit or may be incorporated as one of several components on an integrated circuit. In some examples, the various components and circuitry of the node or other systems may be combined in a SoC architecture.

The above detailed description includes references to the accompanying drawings, which form a part of the detailed description. The drawings show, by way of illustration, specific examples that may be practiced. These examples are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other examples may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as examples may feature a subset of said features. Further, examples may include fewer features than those disclosed in a particular example. Thus, the following claims are hereby incorporated into the Detailed Description, with a claim standing on its own as a separate example. The scope of the examples disclosed herein is to be determined with reference to the appended claims, along with the full scope of equivalents to which such claims are entitled.

What is claimed is:

1. A level shifter circuit, comprising:
one or more p-channel field effect transistors (PFETs) having source and drain terminals coupled, respectively, to a power supply node and a reference node, wherein the one or more PFETs have an electrical over stress (EOS) threshold voltage that is lower than a voltage difference between the power supply node and the reference node; and
a PFET pulldown circuit coupled to a first transistor of the one or more PFETs to limit the voltage difference across at least two terminals of a second PFET of the one or more PFETs to a voltage below the EOS threshold voltage based on the threshold voltage the PFET.

2. The circuit of claim 1, wherein the PFET pulldown circuit includes a PFET that is configured to as pulldown transistor to provide an indicated minimum gate voltage to the second PFET.

3. The circuit of claim 2, wherein the indicated minimum gate voltage is an indicated integer multiple of the threshold voltage of the PFET.

4. The circuit of claim 3, wherein the indicated minimum gate voltage includes a selectable offset voltage.

5. The circuit of claim 2, the PFET has an electrical over stress (EOS) threshold voltage that is lower than a voltage difference between the power supply node and the reference node.

6. The circuit of claim 1, wherein the PFET pulldown circuit includes a PFET that is configured to as pulldown transistor having a source terminal coupled a drain terminal of the second PFET to provide an indicated minimum gate voltage at the drain terminal of the second PFET.

7. The circuit of claim 1, wherein the reference node is a coupled to a zero-volt power supply reference.

8. The circuit of claim 1, wherein the at least two terminals of a second PFET includes a gate and source of the second PFET or a gate and drain of the second PFET.

9. A level shifter device to shift a voltage of a signal from a voltage level of first logic interface to a voltage level of a second logic interface, the device comprising:
first and second power supply nodes to couple, respectively, to first and second power supplies, wherein the first power supply has a voltage that is lower than a voltage of the second power supply;
a reference node to couple to a power supply reference that is shared by the first power supply and the second power supply;
one or more transistors having a source terminal coupled to the second power supply node and a drain terminal coupled to the reference node to provide a shifted output signal responsive to an input signal, wherein the one or more transistors are degraded responsive to a voltage between at least two terminals of the one or more transistors exceeding a threshold value, the threshold value being smaller than a voltage difference between the second power supply and the power supply reference; and
a pulldown transistor coupled to a first transistor of the one or more transistors to limit the voltage difference between the at least two terminals to a voltage below the threshold value based on the threshold voltage the pulldown transistor.

10. The device of claim 9, wherein at least one transistor of the one or more transistors is a p-channel field effect transistor (PFET).

11. The device of claim 9, wherein the pulldown transistor includes a PFET having a first drain terminal coupled to the second power supply node and a first source terminal coupled to the reference node.

12. The device of claim 11, wherein the pulldown transistor is coupled between a first drain terminal of the first transistor and the reference node to limit a voltage at the first drain terminal of the first transistor to at least the threshold voltage the pulldown transistor.

13. The device of claim 11, wherein:
the pulldown transistor is coupled to a gate terminal of the first transistor; and
to limit the voltage difference between the at least two terminals, the pulldown transistor is configured to limit a voltage at a first terminal of the at least two terminals to at least the threshold voltage the pulldown transistor.

14. The device of claim 9, wherein the pulldown transistor is coupled between a pullup and pulldown transistor of a buffer circuit.

15. The device of claim 10, wherein the pulldown transistor includes first and second PFETs, the first PFET having a first drain coupled to the first power supply node and a first source coupled to the reference node, the second PFET having a second drain coupled to the second power supply node and a second source coupled to the reference node.

16. The device of claim 15, further comprising a switching element that is configured to selectively bypass the first PFET.

17. A level shifter circuit, comprising:
first and second power supply nodes to couple, respectively, to first and second power supplies, wherein the first power supply has a voltage that is lower than a voltage of the second power supply;
a reference node to couple to a power supply reference that is shared by the first power supply and the second power supply;
one or more p-channel field effect transistors (PFETs) having a source terminal coupled to the second power supply node and a drain terminal coupled to the reference node to provide a shifted output signal responsive to an input signal, wherein the one or more PFETs have an electrical over stress (EOS) threshold voltage that is lower than a voltage difference between the second power supply and the power supply reference; and
a pulldown PFET coupled to a first transistor of the one or more PFETs to limit the voltage difference between the two terminals of the one or more PFETs to a voltage level below the EOS threshold voltage based on the threshold voltage the pulldown PFET.

18. The circuit of claim 17, wherein the reference node is coupled to a zero-volt power supply reference and pulldown PFET has an EOS threshold voltage that is lower than a voltage difference between the second power supply and the power supply reference.

19. The circuit of claim 17, wherein the two terminals of the one or more PFETs includes a gate and source of the one or more PFETs or a gate and drain of the one or more PFETs.

20. The circuit of claim 17, wherein:
the pulldown PFET has a source terminal coupled to a drain or gate terminal of the one or more PFETs; and
to limit the voltage difference between the two terminals of the one or more PFETs, the pulldown PFET is configured to limit a voltage at the drain or gate terminal the two terminals of the one or more PFETs to at least the threshold voltage the pulldown transistor.
